(19) United States
(12) Patent Application Publication
(10) Pub. No.: US 2023/0152494 A1
(43) Pub. Date: May 18, 2023

(54) COATING FOR REDUCING REFLECTIVITY AND DISPLAY PANEL AND DISPLAY DEVICE

(71) Applicant: TCL CHINA STAR OPTOELECTRONICS TECHNOLOGY CO., LTD., Shenzhen (CN)

(72) Inventor: Guangshuo Cai, Shenzhen (CN)

(73) Assignee: TCL CHINA STAR OPTOELECTRONICS TECHNOLOGY CO., LTD., Shenzhen (CN)

(21) Appl. No.: 17/419,706

(22) PCT Filed: Dec. 30, 2020
(86) PCT No.: PCT/CN2020/141254

§ 371 Date: Jun. 29, 2021

(30) Foreign Application Priority Data
Apr. 21, 2020 (CN) 202010315450.5

(51) Int. Cl. G02B 1/116

(52) U.S. Cl. CPC G02B 1/116

(57) ABSTRACT

A coating configured to reduce reflectivity, a display panel and a display device are disclosed. The coating configured to reduce reflectivity includes at least one set of laminated structure, wherein the laminated structure includes a first coating and a second coating, wherein a refractive index of the first coating is greater than a refractive index of the second coating; and when the laminated structure comprises two or more sets of the laminated structure, the two or more sets of the laminated structure are arranged in a stack.

The present application relates to the field of display technologies, and particularly to a coating for reducing reflectivity, a display panel and a display device.

With the rapid development of touch display panels in mobile phones, televisions, tablet computers, smart watches and other electronic products, people are pursuing higher and higher display performance. Metal materials with a high reflectivity used in the metal electrodes in the TFT backplane of the displays or the metal bridges in the touch screens may reduce contrast and dynamic range of screens, and even limit the application of narrow bezel displays and, affect visual performance of touch display modules.

Therefore, it is necessary to develop a new type of coating configured to reduce reflectivity to overcome the defects in prior art.

### SUMMARY OF INVENTION

The present application aims to provide a coating for reducing reflectivity, which can solve the problems of reduction in contrast and dynamic range of screens induced by metal materials with high reflectivity in prior art.

To achieve above-mentioned goal, a coating for reducing reflectivity is provided by the present application including at least one set of laminated structure, wherein the laminated structure includes a first coating and a second coating, wherein a refractive index of the first coating is greater than a refractive index of the second coating; and when the laminated structure comprises two or more sets of the laminated structure, the two or more sets of the laminated structure are arranged in a stack.

One or more sets of high refractive index coatings and low refractive index coatings arranged in a stack are used to reduce the reflectivity of metal layers disposed under the coating, so as to improve the contrast and dynamic range of screens, and improve the visual performance of touch display modules.

Furthermore, in other embodiments, wherein a material of the first coating comprises molybdenum nitride.

Furthermore, in other embodiments, a material of the second coating comprises one or more of silicon oxide, alumina, tungsten oxide, and molybdenum oxide.

Molybdenum oxide or molybdenum nitride is coated on the metal layers, molybdenum oxide or molybdenum nitride has great light absorption characteristics, therefore the reflectivity of the metal layers can be reduced.

Furthermore, in other embodiments, wherein a material of the first coating comprises molybdenum oxide.

Furthermore, in other embodiments, wherein a material of the second coating comprises one or more of silicon oxide, alumina, tungsten oxide, and indium tin oxide.

Furthermore, in other embodiments, wherein the refractive index of the first coating ranges from 2.5 to 3, and the refractive index of the second coating ranges from 1 to 2.5.

Furthermore, in other embodiments, wherein the refractive index of the first coating ranges from 2 to 2.5, and the refractive index of the second coating ranges from 1 to 2.

To achieve above-mentioned goal, a display panel is also provided by the embodiments, which includes a first gate electrode metal layer, a source and drain metal layer and a touch metal layer, and the coating for reducing reflectivity of the present application. The coating for reducing reflectivity is disposed on the first gate electrode metal layer, and/or the source and drain metal layer, and/or the touch metal layer.

Furthermore, in other embodiments, a material of each of the first gate electrode metal layer, the source and drain metal layer and the touch metal layer comprises one or more of molybdenum, copper, aluminum, and titanium.

Furthermore, in other embodiments, wherein when the coating for reducing reflectivity is disposed on the first gate electrode metal layer, the source and drain metal layer or the touch metal layer, each of the first gate electrode metal layer, the source and drain metal layer, and the touch metal layer with the coating for reducing reflectivity disposed thereon has a reflectivity of 5% to 15%.

To achieve above-mentioned goal, a display device comprising the display panel is provided by this disclosure.

Compared with the prior art, the present application has the following advantages: a coating for reducing reflectivity, a display panel and a display device are provided by the present application. Molybdenum oxide or molybdenum nitride is coated on the metal layers, molybdenum oxide or molybdenum nitride has great light absorption characteristics, therefore the reflectivity of the metal layers can be reduced. Furthermore, one or more sets of high refractive index coatings and low refractive index coatings arranged in a stack are used to further reduce the reflectivity of the metal layers, so as to improve the contrast and dynamic range of screens, and improve the visual performance of touch display modules.

### BRIEF DESCRIPTION OF DRAWINGS

The technical solutions and its advantage effects of the present application will be obvious through detailed description of specific embodiments of the present application in the following with reference to the accompanying drawings.

FIG. 1 is a structural diagram of a coating for reducing reflectivity provided by embodiment 1 of the present application.

coating for reducing reflectivity—100;

laminated structure—10;

a first coating—110; a second coating—120.

### DETAILED DESCRIPTION OF EMBODIMENTS

The present application is further described in detail below with reference to the accompanying drawings and embodiments. Obviously, the following described embodiments are only part of the present application but not all. A person having ordinary skill in the art may obtain other embodiments based on the embodiments provided in the present application without making any creative effort, which all belong to the scope of the present application.

In the description of the present application, it is to be understood that, orientations or position relationships indicated by terms such as “center”, “longitudinal”, “transverse”, “length”, “width”, “thickness”, “upper”, “lower”, “front”, “rear”, “left”, “right”, “vertical”, “horizontal”, “top”, “bottom”, “inner”, “outer”, “clockwise”, and “counterclockwise” are orientations or position relationships shown based on the accompanying drawings, and are merely used for describing the present application and simplifying the description, rather than indicating or implying that the apparatus or element should have a particular orientation or be constructed and operated in a particular orientation, and therefore, should not be construed as a limitation to the present application. In addition, terms “first” and “second” are used only for description purposes, and shall not be understood as indicating or suggesting relative importance or implicitly indicating a quantity of indicated technical features. Therefore, features defined by “first” and “second” may explicitly or implicitly include one or more of the above-mentioned features. In the description of the present application, unless otherwise specifically limited, “a plurality of” means there are at least two elements.

In the embodiments of the present application, it is appreciated that terms “dispose”, “interconnect”, and “connect” should be understood in a broad sense unless otherwise specified and limited. For example, terms “interconnect” and “connect” may refer to fixedly connect, detachably connect, or integrally connect. The terms “interconnect” and “connect” may also refer to mechanically connect, electrically connect, or communicate with each other. The terms “interconnect” and “connect” may also refer to directly connect, indirectly connect through an intermediate medium, intercommunicate interiors of two elements, or interact between two elements. For those of ordinary skill in the art, the specific meanings of the above terms in the embodiments of the present application can be understood according to specific situations.

In prior art, metal materials with high reflectivity used in the metal electrodes in the TFT backplane of the displays or the metal bridges in the touch screens may reduce the contrast and the dynamic range of screens, and even limits the application of narrow bezel display and, affects the visual performance of touch display modules.

A coating for reducing reflectivity is provided by embodiments of the present application which can solve the problems of reduction in contrast and dynamic range of screens induced by the metal materials with a high reflectivity in prior art.

### Embodiment 1

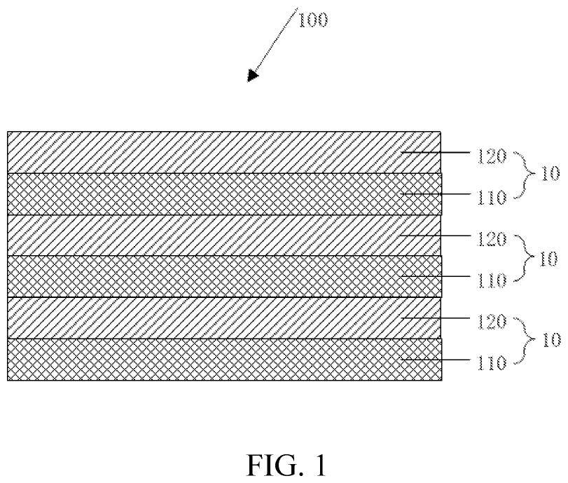

A coating for reducing reflectivity is provided by this embodiment. Please refer to FIG. 1, FIG. 1 is a structural diagram of a coating for reducing reflectivity 100 provided by embodiment of the present application. The coating for reducing reflectivity 100 includes three sets of laminated structures 10.

The laminated structure 100 includes: a first coating 110 and a second coating 120 disposed on the first coating 110.

The three sets of the laminated structure 100 are arranged in a stack. A refractive index of the first coating 110 is greater than a refractive index of the second coating 120.

One or more sets of high refractive index coatings and low refractive index coatings arranged in a stack are used to reduce the reflectivity of metal layers disposed under the coating, so as to improve the contrast and dynamic range of screens, and improve the visual performance of touch display modules.

In this embodiment, a material of the first coating 110 includes molybdenum nitride, and a material of the second coating 120 includes one or more of silicon oxide, alumina, tungsten oxide, and molybdenum oxide. In other embodiments, a material of the second coating 120 can be other oxides, which is not restricted here, as long as the refractive index of the second coating 120 is less than the refractive index of the first coating 110.

Molybdenum oxide or molybdenum nitride is coated on the metal layers, molybdenum oxide or molybdenum nitride has great light absorption characteristics, therefore the reflectivity of the metal layers can be reduced.

A refractive index of the first coating 110 ranges from 2.5-3, and the refractive index of the second coating 120 ranges from 1-2.5.

A display panel is also provided by the embodiments, which includes a first gate electrode metal layer, a source and drain metal layer and a touch metal layer, and the coating for reducing reflectivity 100 of the present application. The coating for reducing reflectivity 100 is disposed on the first gate electrode metal layer, and/or the source and drain metal layer, and/or the touch metal layer.

A material of each of the first gate electrode metal layer, the source and drain metal layer and the touch metal layer includes one or more of molybdenum, copper, aluminum, and titanium.

When the coating for reducing reflectivity 100 is disposed on the first gate electrode metal layer, the source and drain metal layer or the touch metal layer, each of the first gate electrode metal layer, the source and drain metal layer, and the touch metal layer with the coating for reducing reflectivity disposed thereon has a reflectivity of 5% to 15%.

In a display panel provided by the present application, molybdenum oxide or molybdenum nitride is coated on the metal layers, molybdenum oxide or molybdenum nitride has great light absorption characteristics, therefore the reflectivity of the metal layers can be reduced. Furthermore, one or more sets of high refractive index coatings and low refractive index coatings arranged in a stack are used to further reduce the reflectivity of the metal layers, so as to improve the contrast and dynamic range of screens, and improve the visual performance of touch display modules.

A display device includes the display panel is provided by the present application.

### Embodiment 2

A coating for reducing reflectivity in the embodiment has a same structure as the coating for reducing reflectivity 100 provided by the embodiment 1, and also includes three sets of laminated structures 100.

The laminated structure 100 includes a first coating 110 and a second coating 120 disposed on the first coating 110.

The three sets of the laminated structure 100 are arranged in a stack. A refractive index of the first coating 110 is greater than a refractive index of the second coating 120.

One or more sets of high refractive index coatings and low refractive index coatings arranged in a stack are used to reduce the reflectivity of metal layers disposed under the coating, so as to improve the contrast and dynamic range of screens, and improve the visual performance of touch display modules.

Differences between this embodiment and embodiment 1 is that: in this embodiment, a material of the first coating 110 includes molybdenum oxide, and a material of the second coating 120 includes one or more of silicon oxide, alumina, tungsten oxide, and indium tin oxide. In other embodiments, a material of the second coating 120 can be other oxides, which is not restricted here, as long as the refractive index of the second coating 120 is less than the refractive index of the first coating 110.

Molybdenum oxide or molybdenum nitride is coated on the metal layers, molybdenum oxide or molybdenum nitride has great light absorption characteristics, therefore the reflectivity of the metal layers can be reduced.

A refractive index of the first coating 110 ranges from 2-2.5, and the refractive index of the second coating 120 ranges from 1-2.

A display panel is also provided by the embodiments, which includes a first gate electrode metal layer, a source and drain metal layer and a touch metal layer, and the coating for reducing reflectivity 100 of the present application. The coating for reducing reflectivity 100 is disposed on the first gate electrode metal layer, and/or the source and drain metal layer, and/or the touch metal layer.

A material of each of the first gate electrode metal layer, the source and drain metal layer and the touch metal layer includes one or more of molybdenum, copper, aluminum, and titanium.

When the coating for reducing reflectivity 100 is disposed on the first gate electrode metal layer, the source and drain metal layer or the touch metal layer, each of the first gate electrode metal layer, the source and drain metal layer, and the touch metal layer with the coating for reducing reflectivity disposed thereon has a reflectivity of 5% to 15%.

In a display panel provided by the present application, molybdenum oxide or molybdenum nitride is coated on the metal layers, molybdenum oxide or molybdenum nitride has great light absorption characteristics, therefore the reflectivity of the metal layers can be reduced. Furthermore, one or more sets of high refractive index coatings and low refractive index coatings arranged in a stack are used to further reduce the reflectivity of the metal layers, so as to improve the contrast and dynamic range of screens, and improve the visual performance of touch display modules.

A display device includes the display panel is provided by the present application.

The present application has the following advantages: a coating for reducing reflectivity, a display panel and a display device are provided by the present application. Molybdenum oxide or molybdenum nitride is coated on the metal layers, molybdenum oxide or molybdenum nitride has great light absorption characteristics, therefore the reflectivity of the metal layers can be reduced. Furthermore, one or more sets of high refractive index coatings and low refractive index coatings arranged in a stack are used to further reduce the reflectivity of the metal layers, so as to improve the contrast and dynamic range of screens, and improve the visual performance of touch display modules.

In the above embodiments, description of each embodiment has its own emphasis. For part with no detailed description in one embodiment, please refer to relevant description of other embodiments.

The coating for reducing reflectivity, display panel and display device are provided by the embodiment of the application are described in detail. Specifically, examples are used to illustrate principles and embodiments of the present application. The description of the above embodiments is only intended to help understand the technical schemes and core concepts of this disclosure. It is noted that those with ordinary skill in the technique field could make various modifications to technical schemes or or equivalent replacements to part of the technical features described in embodiments above-mentioned, and these modifications and replacement don't make the substantial of corresponding technical schemes out of the scope of technical schemes of embodiments of the present application.

What is claimed is:

1. A coating for reducing reflectivity comprising:
at least one set of laminated structure, wherein the laminated structure comprises a first coating and a second coating, wherein a refractive index of the first coating is greater than a refractive index of the second coating; and when the laminated structure comprises two or more sets of the laminated structure, the two or more sets of the laminated structure are arranged in a stack.

2. The coating configured to reduce reflectivity according to claim 1, wherein a material of the first coating comprises molybdenum nitride.

3. The coating configured to reduce reflectivity according to claim 2, wherein a material of the second coating comprises one or more of silicon oxide, alumina, tungsten oxide, and molybdenum oxide.

4. The coating configured to reduce reflectivity according to claim 1, wherein a material of the first coating comprises molybdenum oxide.

5. The coating configured to reduce reflectivity according to claim 4, wherein a material of the second coating comprises one or more of silicon oxide, alumina, tungsten oxide, and indium tin oxide.

6. The coating configured to reduce reflectivity according to claim 2, wherein the refractive index of the first coating ranges from 2.5 to 3.

7. A display panel comprising a first gate electrode metal layer, a source and drain metal layer, a touch metal layer, and a coating configured to reduce reflectivity,
wherein the coating configured to reduce reflectivity comprising at least one set of laminated structure, wherein the laminated structure comprises a first coating and a second coating, wherein a refractive index of the first coating is greater than a refractive index of the second coating; and when the laminated structure comprises two or more sets of the laminated structure, the two or more sets of the laminated structure are arranged in a stack;
the coating configured to reduce reflectivity is disposed on the first gate electrode metal layer, the source and drain metal layer, or the touch metal layer.

8. The display panel according to claim 7, wherein a material of each of the first gate electrode metal layer, the source and drain metal layer and the touch metal layer comprises one or more of molybdenum, copper, aluminum, and titanium.

9. The display panel according to claim 7, wherein each of the first gate electrode metal layer, the source and drain metal layer, and the touch metal layer with the coating configured to reduce reflectivity disposed thereon has a reflectivity of 5% to 15%.

10. The display panel according to claim 7, wherein a material of the first coating comprises molybdenum nitride.

11. The display panel according to claim 10, wherein a material of the second coating comprises one or more of silicon oxide, alumina, tungsten oxide, and molybdenum oxide.

12. The display panel according to claim 7, wherein a material of the first coating comprises molybdenum oxide.

13. The display panel according to claim 12, wherein a material of the second coating comprises one or more of silicon oxide, alumina, tungsten oxide, and indium tin oxide.

14. The display panel according to claim 10, wherein the refractive index of the first coating ranges from 2.5 to 3.

15. A display device comprising a display panel, wherein the display panel comprises a first gate electrode metal layer, a source and drain metal layer, a touch metal layer, and a coating configured to reduce reflectivity,
wherein the coating configured to reduce reflectivity comprising at least one set of laminated structure, wherein the laminated structure comprises a first coating and a second coating, wherein a refractive index of the first coating is greater than a refractive index of the second coating; and when the laminated structure comprises two or more sets of the laminated structure, the two or more sets of the laminated structure are arranged in a stack;
the coating configured to reduce reflectivity is disposed on the first gate electrode metal layer, the source and drain metal layer, or the touch metal layer.

16. The display device according to claim 15, wherein a material of the first coating comprises molybdenum nitride.

17. The display device according to claim 16, wherein a material of the second coating comprises one or more of silicon oxide, alumina, tungsten oxide, and molybdenum oxide.

18. The display device according to claim 15, wherein a material of the first coating comprises molybdenum oxide.

19. The display device according to claim 18, wherein a material of the second coating comprises one or more of silicon oxide, alumina, tungsten oxide, and indium tin oxide.

20. The display device according to claim 16, wherein the refractive index of the first coating ranges from 2.5 to 3.
